(19) United States
(12) Patent Application Publication
(10) Pub. No.: US 2012/0081140 A1
(43) Pub. Date: Apr. 5, 2012

(54) PROBE CARD

(76) Inventors: Yun Hee Shim, Gyeonggi-do (KR); Sung Hee Yoon, Gyeonggi-do (KR); Seung Ho Yoo, Gyeonggi-do (KR); Byung Chang Song, Gyeonggi-do (KR); In Buhm Chung, Gyeonggi-do (KR); Dong Il Kim, Gyeonggi-do (KR)

(21) Appl. No.: 13/322,416

(22) PCT Filed: Apr. 22, 2010
(86) PCT No.: PCT/KR10/02540

§ 371 Date: Nov. 23, 2011

(30) Foreign Application Priority Data
Jul. 8, 2009 (KR) 10-2009-0062161

(51) Int. Cl. G01R 1/067

(52) U.S. Cl. 324/755.03; 324/755.01

(57) ABSTRACT

Provided is a probe card which has a space transformer which may be effectively changed to correspond to a change in wafer chip structure and is capable of maximizing acceptable channels of the space transformer. The probe card for testing a semiconductor chip on a wafer includes: a space transformer body in which a plurality of unit probe modules are arranged at intervals; a main circuit board to which an electrical signal is applied from an external test device; a reinforcement plate for supporting the main circuit board such that the unit probe modules become stable against an external effect; a standing conductive medium which is inserted into a penetration portion provided in the space transformer body; a lower surface circuit board in which the standing conductive medium is electrically connected to the unit probe module as a flexible conductive medium and the standing conductive media are mounted; and a mutual connection member for electrically connecting the lower surface circuit board to the main circuit board.

### TECHNICAL FIELD

This disclosure relates to a probe card, and more particularly, to a probe card which has a space transformer which is effectively changed to correspond to a change in wafer chip structure and is capable of maximizing acceptable channels of the space transformer.

### BACKGROUND ART

In general, a semiconductor fabrication process is divided into preprocessing and postprocessing. The preprocessing is a fabrication process for forming an integrated circuit pattern on a wafer, and the postprocessing is an assembling process for separating a wafer into a plurality of chips, connecting a conductive lead or ball to each chip for transmission of an electrical signal to an external device, and performing molding on the chip with epoxy or the like, thereby configuring an integrated circuit package.

Before performing the assembling process, an electrical die sorting (EDS) process for inspecting electrical characteristics of each chip is performed. The EDS process is a process for determining defective chips from the chips of the wafers, repairing repairable chips, and removing unrepairable chips to reduce time and cost in the subsequent assembling process.

The EDS process is conducted on a probe station. The probe station is typically provided with a probe head, which includes a probe chuck on which a wafer to be inspected is placed and a probe card. A number of fine probes are provided on the probe card, and each fine probe electrically comes in contact with a pad of each chip of the wafer to determine defectiveness of the corresponding chip.

With the development of the semiconductor technology, a greater number of chips are formed on a single wafer for cost reduction and productivity improvement. Recently, with the advent of 300 mm wafer processing is, an increase in the number of chips to be formed on a wafer has been accelerated. Hence, in the filed of wafer testing, it is important to develop a large-area probe card.

Referring to the attached drawings, FIG. 1 is a plan view illustrating a probe card according to a related art. FIG. 2 is a plan view illustrating a probe card according to another related art. FIG. 3 is a plan view illustrating a probe card according to a related art. FIG. 4 is an enlarged plan view of the part A illustrated in FIG. 3. FIG. 5 is a cross-sectional view taken along the line B-B′ illustrated in FIG. 4.

Existing large-area test probe cards are classified into board type and block type in terms of a space transformer. A board type is, as illustrated in FIG. 1, a type in which a plurality of fine probes 2 are provided on a space transfer 1 having a size corresponding to a wafer to be tested, for example, a ceramic board. The type has advantages in that a subsequent assembling operation of the space transformer is easy and a probe arrangement is stably maintained. However, unlike a general ceramic board, the ceramic board for the space transformer is equipped with electric wiring for electrical connection between the probe and a circuit board, and, hence, there are problems in that the fabrication process thereof is complicated, which results in increased fabrication cost. The problem of the ceramic board for the space transformer described above becomes more serious for a large-area board, and currently, fabrication of a ceramic board for a space transformer corresponding to a 300 mm wafer is difficult.

On the other hand, the block type is, as illustrated in FIG. 2, a type in which an area to be tested is divided into several blocks 12, a plurality of fine probes 13 are mounted on each of the blocks 12, and each of the blocks 12 is precisely arranged on a block fixing frame 11, thereby fabricating a large-area probe card. In terms of fabrication process, the block type has an advantage in that when a problem occurs during the fabrication process or during use, only the corresponding block needs to be replaced. However, as the area to be tested is increased, the number of blocks and the lengths of the blocks to be precisely arranged also increase, so that there are problems in that time consumed to precisely arrange the blocks is increased and an arrangement of the blocks may be deteriorated when the probe card is exposed to a test environment to be used.

A technique developed to overcome the above-mentioned problems is disclosed in Korea Patent Application No. 2007-0088270 (PROBE CARD AND METHOD FOR FABRICATING THE SAME).

The probe card disclosed in Korea Patent Application No. 2007-0088270 (PROBE CARD AND METHOD FOR FABRICATING THE SAME) is, as illustrated in FIGS. 3 to 5, configured by a combination of a space transformer 20 and a lower circuit board 40. In the probe card, a plurality of unit probe modules 30 are arranged at intervals on a surface of a body of the space transformer 20, and a penetration portion 23 that penetrates the body of the space transformer is formed at a position distant from each unit probe module 30. In addition, in the penetration portion 23, a vertical conductive medium 25 is positioned. One end of the vertical conductive medium 25 is bonded to the unit probe module 30 by a wire 31, and the other end of the vertical conductive medium 25 is bonded to the lower circuit board 40 by a wire 41. Therefore, the lower circuit board 40 and the unit probe module 30 of the space transformer 20 are electrically connected by the wire 31 of the vertical conductive medium 25, such that an electrical signal is transmitted. In addition, as illustrated in FIGS. 4 and 5, the lower circuit board 40 is connected to a main circuit board 60 by a mutual connection member 50. Therefore, the main circuit board 60 and the unit probe module 30 are electrically connected to each other such that an electrical signal is transmitted.

As illustrated in FIG. 5, the lower circuit substrate 40 mounted on the space transformer 20 of the probe card according to the related art is limited in terms of position by the unit probe module 30 positioned thereabove.

Specifically, since the existing lower circuit boards 40 are positioned on the opposite surfaces of the space transformer 20 to the corresponding unit probe modules, the position of the lower circuit board 40 is set and limited depending on the pattern of the unit probe module 30. In addition, since the lower circuit board 40 is set depending on the pattern of the unit probe module 30, the same pattern for electrical connection of the mutual connection member between the lower circuit board 40 and the main circuit board 60 has to be formed therebetween. Therefore, it is difficult to use the main circuit board for general purposes. Furthermore, since a body 21, the lower circuit board 40, and the main printed circuit board of the space transformer 20 are set depending on the pattern of the unit probe module 30, there is a disadvantage in that when the pattern of the unit probe module 30 is changed, a pattern of the lower circuit board 40 and the main printed circuit board have to be changed.

in addition, as illustrated in FIG. 5, an electrical signal applied to the unit probe module 30 is branched off from the main circuit board 60 and transmitted to the unit probe module 30 through the mutual connection member 50, the lower circuit board 40, and the vertical conductive medium 25. Therefore, there is a disadvantage in that the distance from the main circuit board 60 to the unit probe module 30 is far and thus signal integrity is unstable.

Moreover, a channel between the main circuit board 60 and the unit probe module 30 is limited by the lower circuit board 40 of which the position is limited, so that there is a difficulty in controlling the space transformer 20.

### DISCLOSURE

### Technical Problem

This disclosure provides a probe card having a configuration in which an electrical signal is branched off from a lower surface circuit board and transmitted to each probe module, so that a main circuit board may be used for general purpose irrespective of a pattern of a probe module, stable signal integrity is achieved as the electrical signal is branched off from the lower surface circuit board, and channels are maximized as channels connected to the probe modules are formed on a large-area lower surface circuit board.

### Technical Solution

In one aspect, there is provided a probe card for testing a semiconductor chip on a wafer, including: a space transformer body in which a plurality of unit probe modules are arranged at intervals; a main circuit board to which an electrical signal is applied from an external test device; a reinforcement plate for supporting the main circuit board such that the unit probe modules become stable against an external effect; a standing conductive medium which is inserted into a penetration portion provided in the space transformer body; a lower surface circuit board in which the standing conductive medium is electrically connected to the unit probe module as a flexible conductive medium and the standing conductive media are mounted; and a mutual connection member for electrically connecting the lower surface circuit board to the main circuit board.

The lower surface circuit board may include a single or a plurality of circuit boards and have an entire area corresponding to that of the space transformer, a plurality of the unit probe modules may be connected to each lower surface circuit board, and the standing conductive medium may be mounted to protrude from the lower surface circuit board.

The standing conductive medium may be mounted to the lower surface circuit board by a surface mount technique or an insertion mount technique.

The lower surface circuit board may be a printed circuit board, and the printed circuit board may be provided with lands to which the standing conductive medium is connected and lands with which the mutual connection member comes in contact.

The standing conductive medium may be one of a pin connector, a cut-surface printed circuit hoard connector, a three-dimensional pattern connector, a blade connector, a rigid printed circuit board connector, a molded metal connector, a multi-stage connector and a silicon connector.

One surface of the standing conductive medium may have a ground/power transmission line electrically connected to a flat conductive pattern and a condenser, and the other surface of the standing conductive medium may have a conductive pattern mounted on the lower surface circuit board.

The condenser may be mounted to the one surface of the standing conductive medium.

The pin connector may be positioned to be inserted into the penetration portion, and may include: a housing provided with penetration holes; and a conductor of which one end is positioned on a side where the unit probe module is positioned and the other end is positioned on a side of the power surface circuit board such that the unit probe module and the lower surface circuit board are electrically connected to each other in a state where the conductive is inserted into the penetration hole.

The condenser may be mounted to the housing.

The one end of the conductor and the unit probe module may be wire bonded.

The flexible conductive medium may be connected by one or a combination of wire bonding, a flexible circuit board, an anisotropic conductive film, a sub printed circuit board, and a solder ball.

### Advantageous Effects

In the disclosed probe card, the lower surface circuit board mounted to the space transformer has a large area corresponding to an area of the space transformer body, so that there is an advantage in that the main circuit board can be used for general purpose irrespective of the pattern of the probe module in a state where the lower surface circuit board is connected to the main circuit board.

In the disclosed probe card, the standing conductive medium is mounted to the space transformer body in the state where the standing conductive medium is mounted on the lower surface circuit board, so that a problem in which a vertical conductive medium and a lower circuit board are arranged to correspond to each probe module as in the related art can be solved.

In the disclosed probe card, the standing conductive medium is mounted on the lower surface circuit board, and the standing conductive medium is inserted into the penetration portion of the space transformer to be mounted. Therefore, the mounting operation is effective in terms of operation as compared with an operation of inserting the vertical conductive medium into the penetration portion provided in the space transformer body and bonding both ends of wires to the vertical conductive medium and the lower circuit board as in the related art, so that there are advantages in that productivity is excellent and the probe card is structurally stable.

In the disclosed probe card, the electrical signal applied to the main circuit board is branched off from the lower surface circuit board via the mutual connection member. Thus, the distance from the branched point to the probe module is shorter than the distance branched off from the existing main circuit board. Therefore, there is an advantage in that signal integrity is excellent.

### DESCRIPTION OF DRAWINGS

The above and other aspects, features and advantages of the disclosed exemplary embodiments will be more apparent from the following detailed description taken in conjunction with the accompanying drawings in which:

FIG. 1 is a plan view illustrating a probe card according to a related art;

FIG. 2 is a plan view illustrating a probe card according to another related art;

FIG. 3 is a plan view illustrating a probe card according to a related art;

FIG. 4 is an enlarged plan view of the part A illustrated in FIG. 3;

FIG. 5 is a cross-sectional view taken along the line B-B′ illustrated in FIG. 4;

FIG. 6 is a plan view of a probe card according to an embodiment;

FIG. 7 is an enlarged plan view of the part C of FIG. 6;

FIG. 8 is a cross-sectional view taken along the line D-D′ illustrated in FIG. 7;

FIG. 9 is a cross-sectional view of a part where a screw is tightened;

FIG. 10 is a perspective view of FIG. 7;

FIG. 11 is an exploded perspective view of FIG. 10;

FIG. 12 is an enlarged view of the part E illustrated in FIG. 10;

FIG. 13 is an exploded perspective view of a pin connector;

FIGS. 14 to 20 are conceptual views illustrating a connector according to another embodiment;

FIG. 21 is a top view of a lower circuit board; and

FIG. 22 is a bottom view of the lower circuit board.

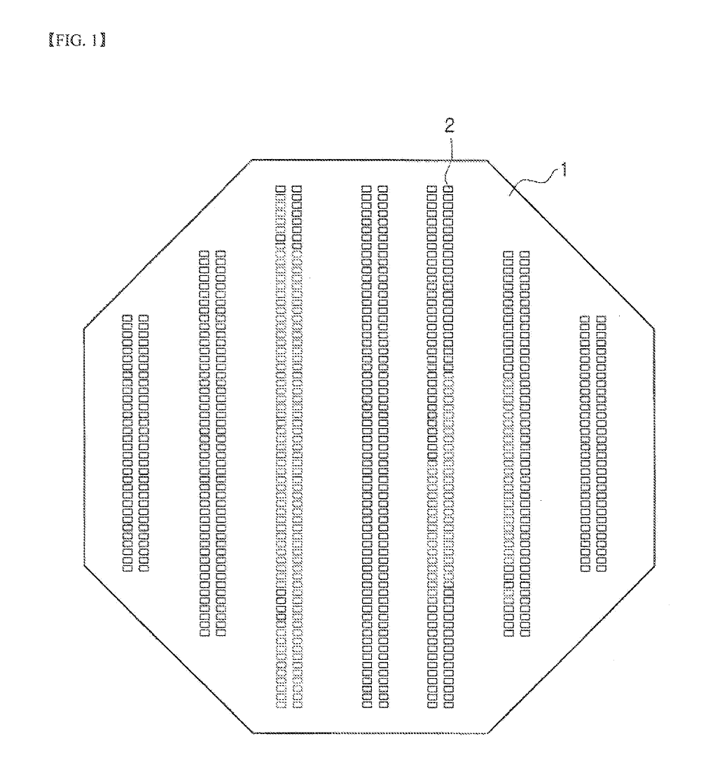

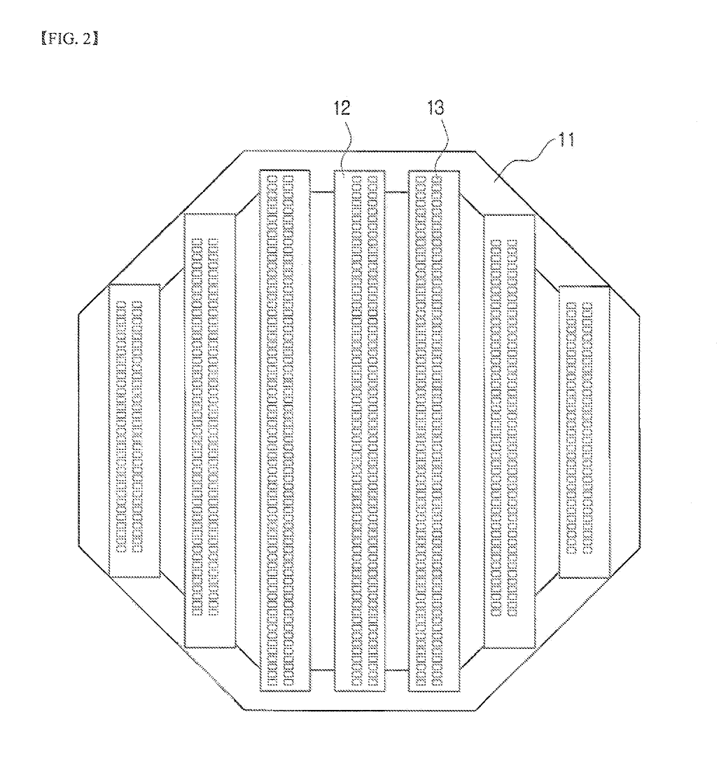

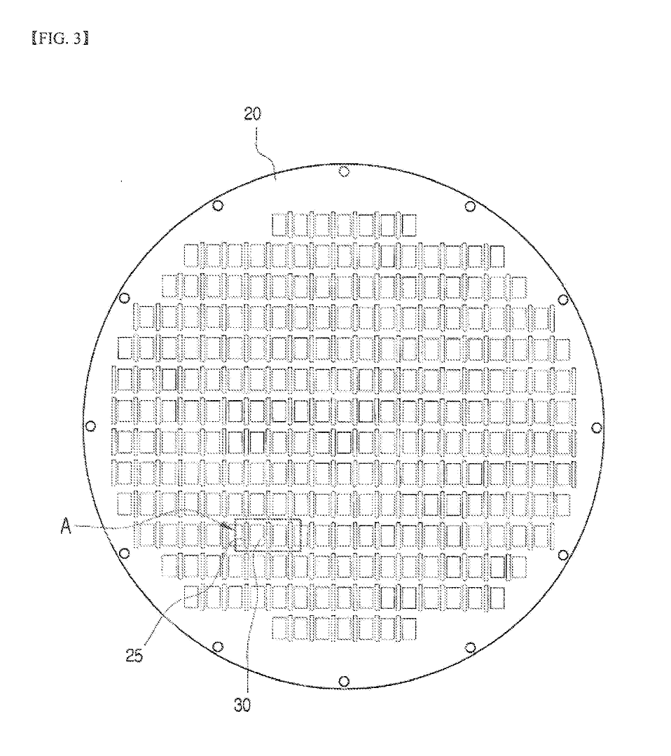

### BEST MODE

Hereinafter, reference will now be made in detail to various embodiments, examples of which are illustrated in the accompanying drawings and described below. While description will be made in conjunction with example embodiments, it will be understood that the present description is not intended to be limitative.

### MODE FOR INVENTION

Exemplary embodiments now will be described more fully hereinafter with reference to the accompanying drawings, in which exemplary embodiments are shown. This disclosure may, however, be embodied in many different forms and should not be construed as limited to the exemplary embodiments set forth therein. Rather, these exemplary embodiments are provided so that this disclosure will be thorough and complete, and will fully convey the scope of this disclosure to those skilled in the art. In the description, details of well-known features and techniques may be omitted to avoid unnecessarily obscuring the presented embodiments.

The terminology used herein is for the purpose of describing particular embodiments only and is not intended to be limiting of this disclosure. As used herein, the singular forms a, an and the are intended to include the plural forms as well, unless the context clearly indicates otherwise. Furthermore, the use of the terms a, an, etc. does not denote a limitation of quantity, but rather denotes the presence of at least one of the referenced item. It will be further understood that the terms comprises and/or comprising, or includes and/or including when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements. The shape, size and regions, and the like, of the drawing may be exaggerated for clarity.

A probe card according to exemplary embodiments will be described in detail with reference to the accompanying drawings.

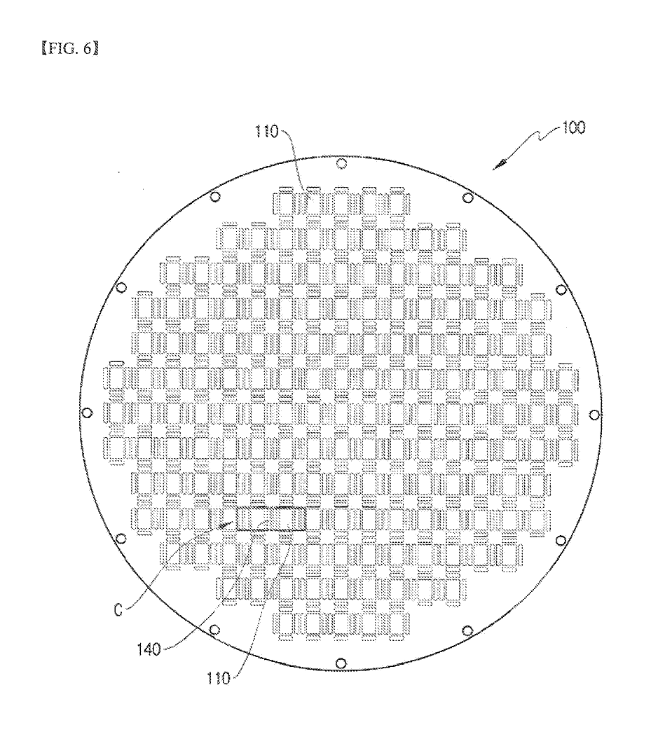

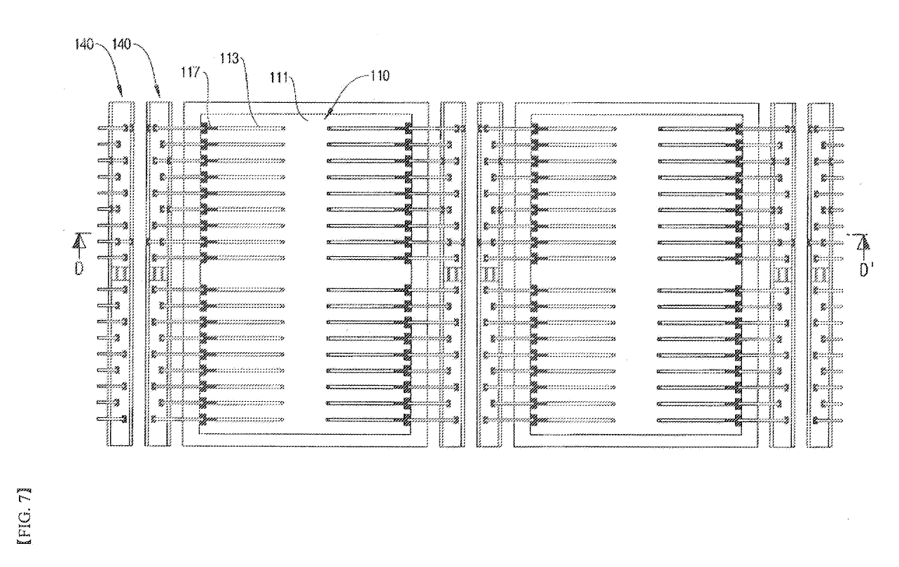

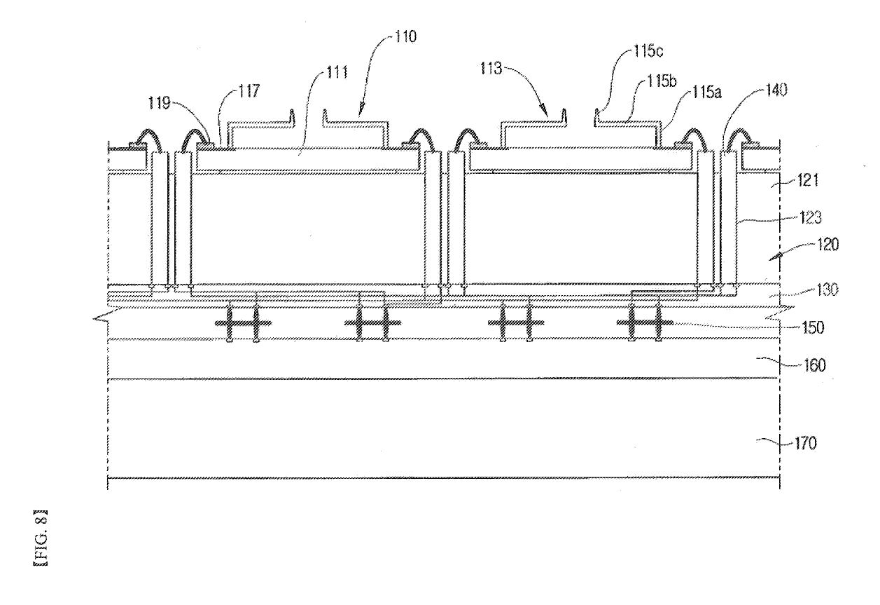

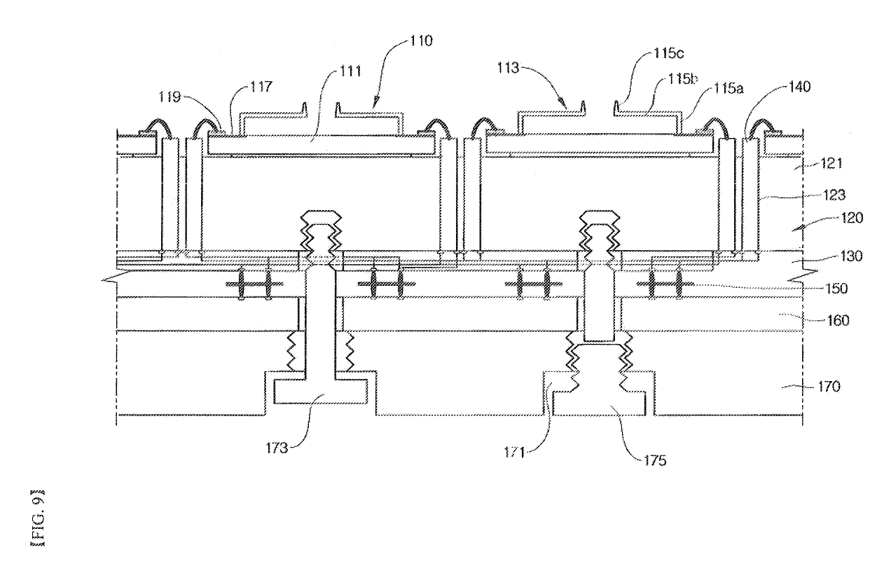

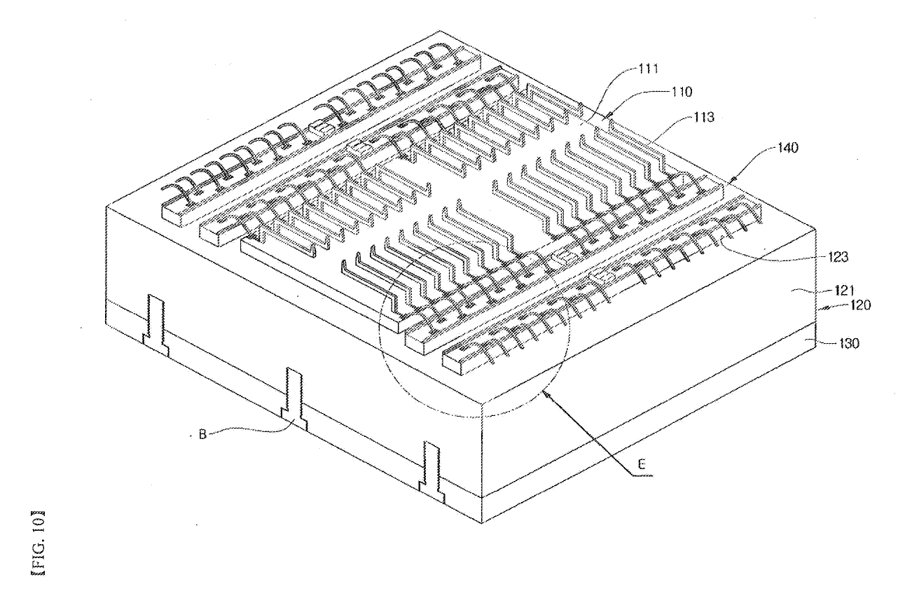

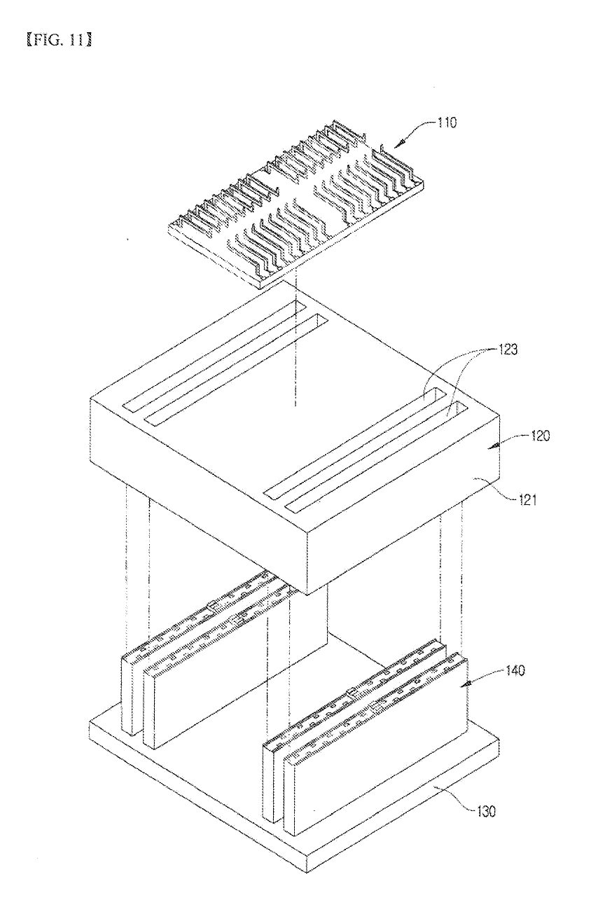

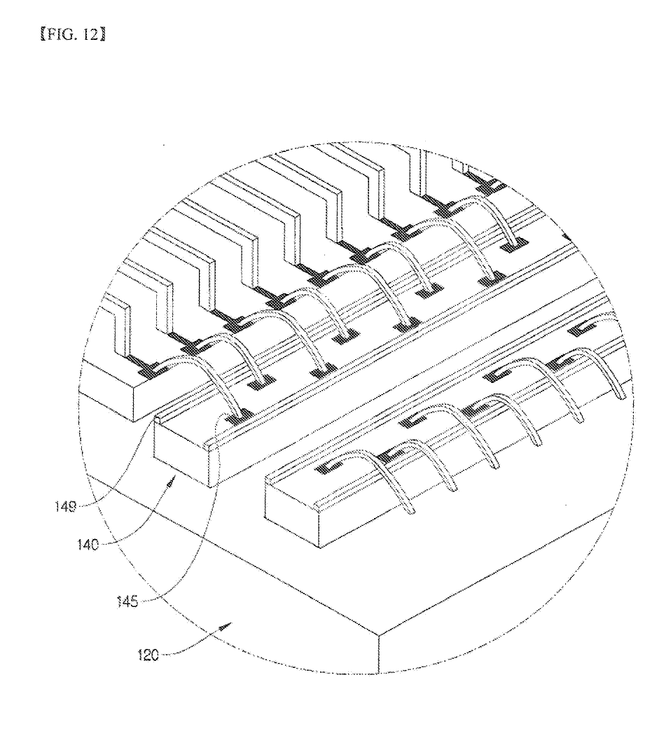

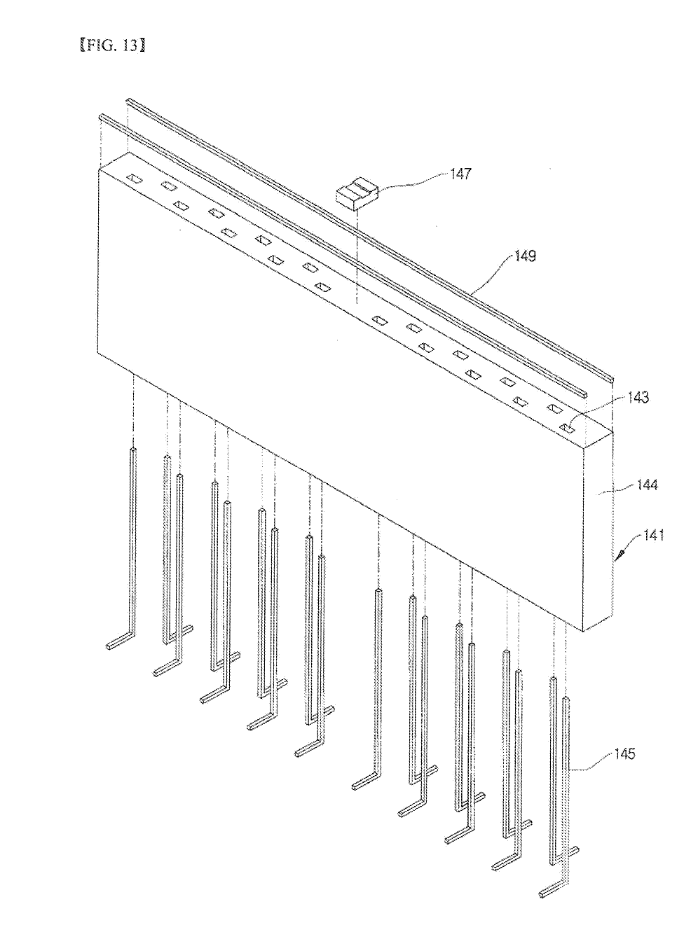

FIG. 6 is a plan view of a probe card according to an embodiment. FIG. 7 is an enlarged plan view of the part C of FIG. 6. FIG. 8 is a cross-sectional view taken along the line D-D′ illustrated in FIG. 7. FIG. 9 is a cross-sectional view of a part where a screw is tightened. FIG. 10 is a perspective view of FIG. 7. FIG. 11 is an exploded perspective view of FIG. 10. FIG. 12 is an enlarged view of the part E illustrated in FIG. 10. FIG. 13 is an exploded perspective view of a pin connector. And, FIGS. 14 to 20 are conceptual views illustrating a connector according to another embodiment.

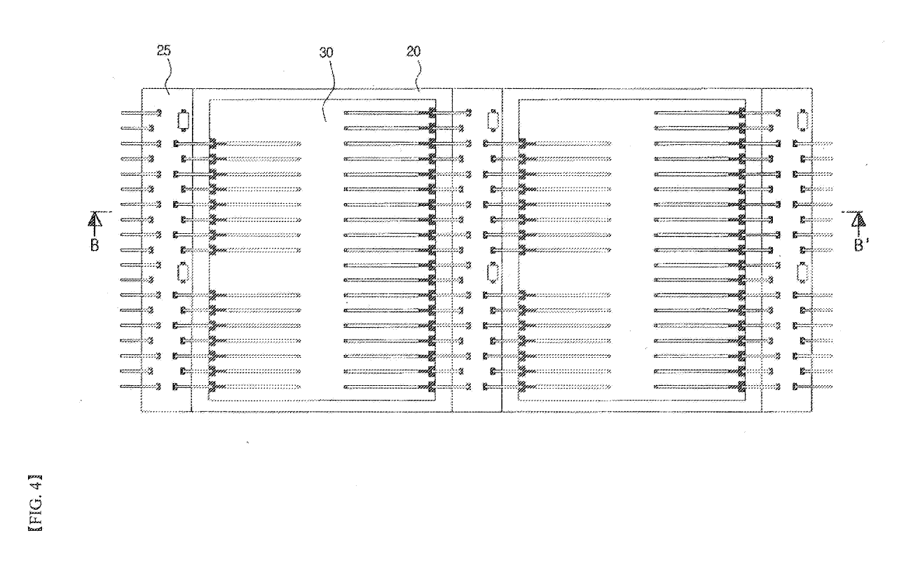

As illustrated in FIGS. 4 to 9, a probe card 100 has a configuration in which a main circuit board 160 and a space transformer 20 are sequentially stacked. Unit probe modules 110 that electrically come in contact with a semiconductor chip (not shown) to be inspected are positioned on the space transformer 120, and an electrical signal generated due to contact between the unit probe module 110 and the semiconductor chip is transmitted to the main circuit board 160.

A mutual connection member 150 is positioned between the main circuit board 160 and the space transformer 120 to electrically connect the main circuit board 160 and the unit probe module 110 to each other, and a reinforcement plate 170 is mounted to a rear surface of the main circuit board 160 to reinforce the main circuit board 160.

The probe card having such a configuration will be described in detail.

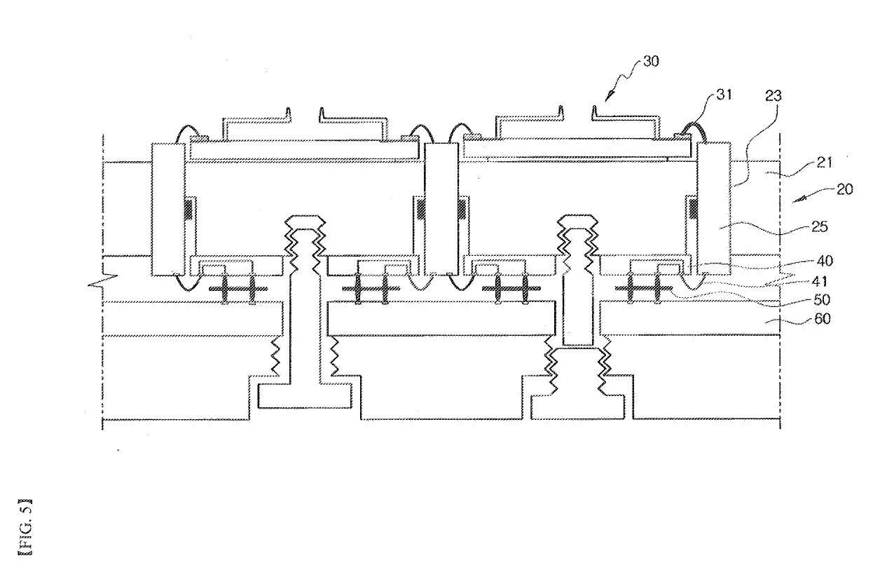

The space transformer 120 of the probe card 110 has a size corresponding to an area of a wafer to be tested as illustrated in FIGS. 4 and 5. A plurality of the unit probe modules 110 are arranged at intervals on the space transformer 120. The plurality of the unit probe modules 110 may be arranged repeatedly at predetermined intervals.

In addition, penetration portions 123 are provided in a body 121 of the space transformer 120 to be spaced from the unit probe modules 110 at predetermined intervals as illustrated in FIG. 7. The penetration portion 123 penetrates both surfaces (upper and lower surfaces) of the body 121 of the space transformer 120.

The penetration portions 123 may be provided at positions distant from at least one side surface from among the four, i.e., upper, lower, left and right, surfaces of the unit probe module 119. That is, the penetration portions 123 are formed on one side or both sides of the unit probe module 110 or formed at positions distant from three or four side surfaces.

In addition, as illustrated in FIGS. 8 and 9, a space transformer lower surface circuit board (hereinafter, referred to as a lower surface circuit board 130? having an area corresponding to that of the space transformer 120 is positioned at the body 121 of the space transformer 120. Therefore, the body 121 and the lower surface circuit board 130 of the space transformer 120 have areas corresponding to that of a wafer.

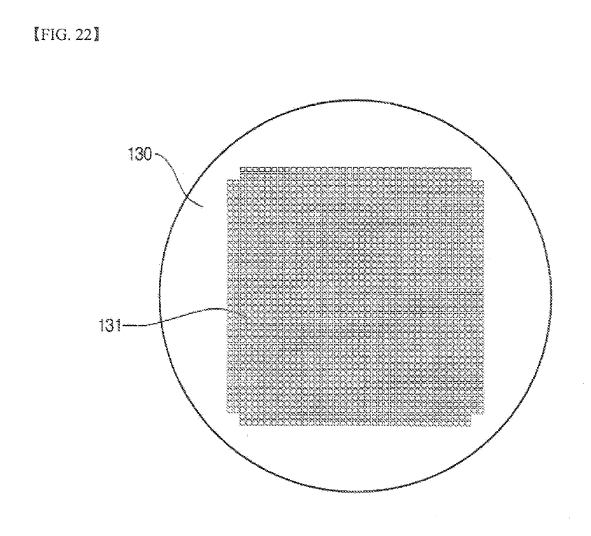

A connector 140 to be inserted through the penetration portion 123 provided in the space transformer body 121 is mounted on the lower surface circuit board 130. The connector 140 is mounted on the lower surface circuit board 130 by surface mount technology or insertion mount technology. The lower surface circuit board 130 is a printed circuit board, and lands 131 are formed on a top surface (FIG. 21) and a bottom surface (FIG. 22) of the lower surface circuit board 130 as illustrated in FIGS. 21 and 22 so that the connector 140 and the mutual connection member 150 are connected to each other. When the lower surface circuit board 130 is fixed to the body 121, the lower surface circuit board 130 is fixed to the space transformer body 121 while the connector 140 is inserted into the penetration portion 123.

For reference, the number of unit probe modules 110 positioned between the connectors 140 inserted through the penetration portions 123 of the space transformer body 121 may be one or more. That is, a single or a plurality of unit probe modules 110 may be commonly or individually connected to a particular connector.

The unit probe module 110 provided on the space transformer 120 may have a size corresponding to a size of a semiconductor chip or 20 to 100% of the size of the semiconductor chip. As the size of the unit probe module 110 is increased, fabrication cost is increased, and production yield is decreased. However, there is an advantage in that a probe card assembling operation becomes easy. On the other hand, as the size of the unit probe module 110 is decreased, fabrication cost is decreased, and production yield is increased. However, there is a disadvantage in that the probe card assembling operation is complex. According to an embodiment, considering the advantage and the disadvantage of the unit probe module 110 in terms of size, the unit probe module 110 is proposed to have a size corresponding to that of the semiconductor chip or to 200 to 100% of the size of the semiconductor chip.

As illustrated in FIGS. 8 and 9, the unit probe module 110 includes an insulating probe body 111 and fine probes 113 provided on the probe body 111. The fine probe 113 includes a column 115a, a beam 115b, and a tip 115c, and the tip 115c has a function of practically coming in contact with a pad of a semiconductor chip to be inspected. Besides the fine probes 113, a wire 117 and a pad 119 for transmitting an electrical signal generated when the fine probe 113 and the semiconductor chip come in contact with each other to the main circuit board 160 are provided on the top surface of the probe body 111

As described above, the electrical signal generated when the unit probe module 110 and the semiconductor chip come in contact with each other is transmitted to the main circuit board 160. Here, the connector 140 serves as a primary medium of electrical transmission between the unit probe module 110 and the main circuit board 160. The electrical signal transmitted to the connector 140 is finally transmitted to the main circuit board 160 through the lower surface circuit board 130 and the mutual connection member 150 provided under the lower surface of the space transformer 120. The lower surface circuit board 130 will be described in detail.

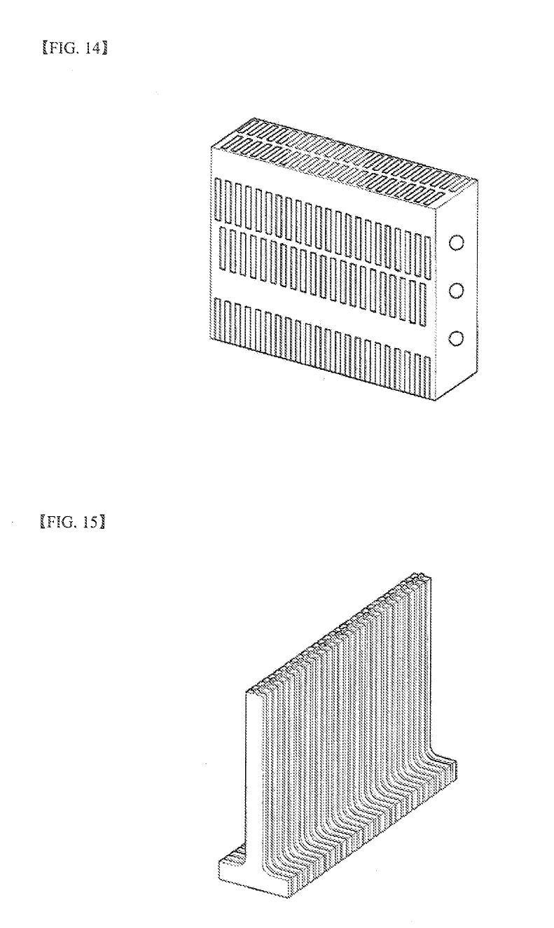

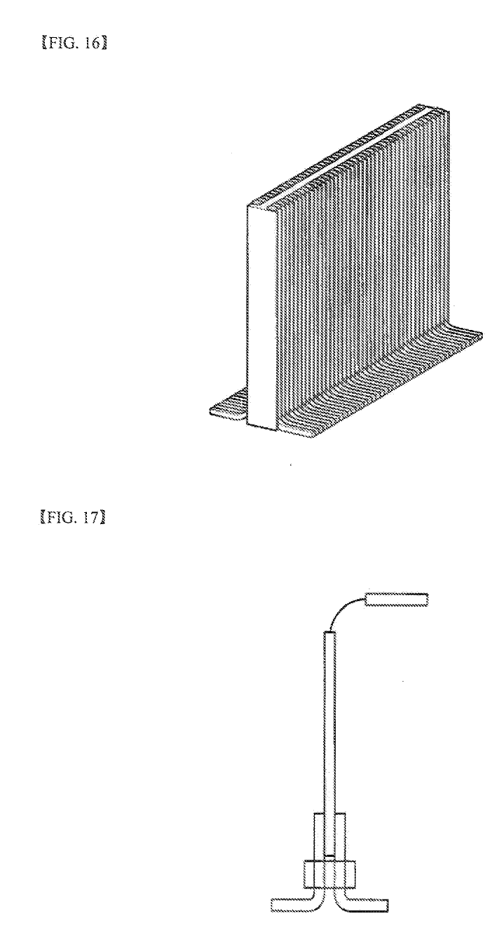

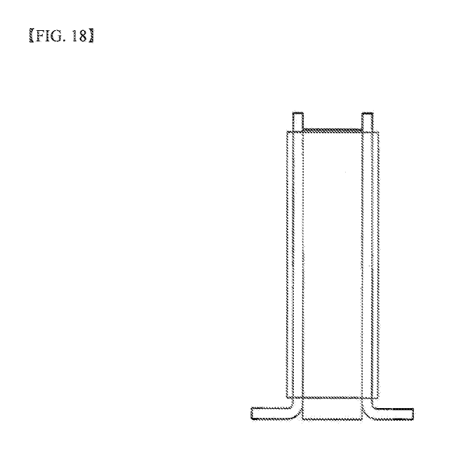

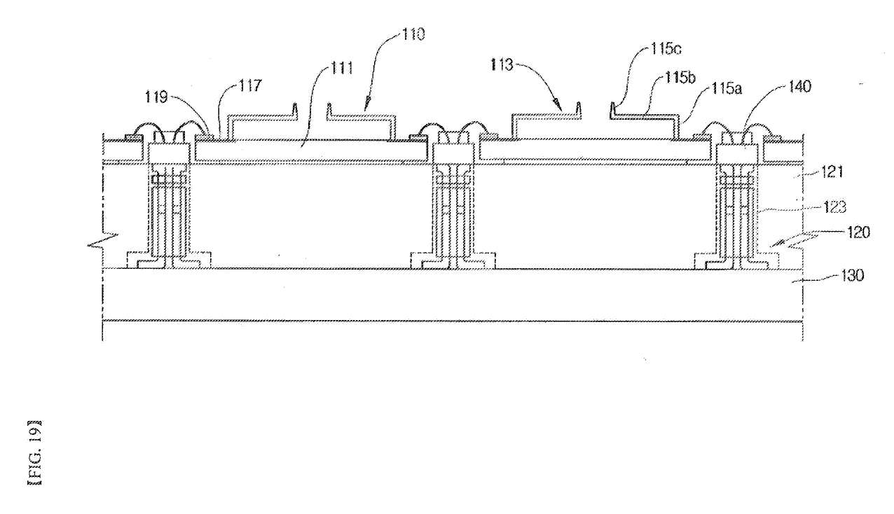

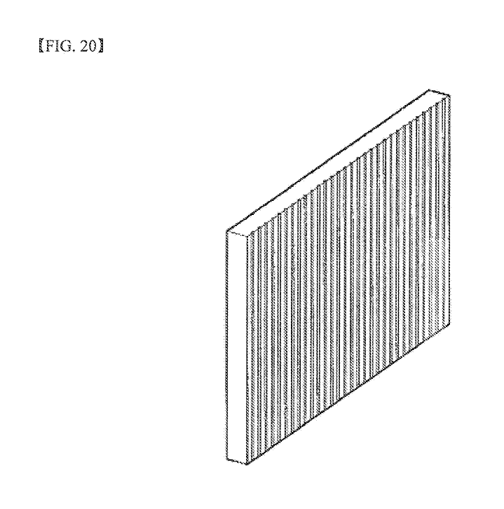

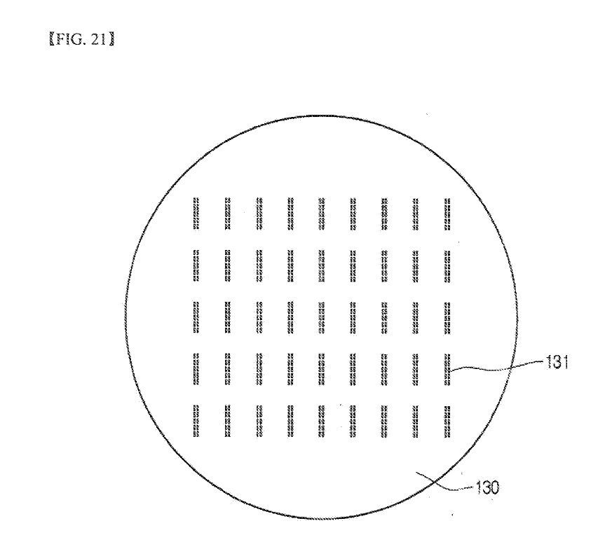

In an embodiment, the connector 140 which is a standing conductive medium may have a shape of a pin connector 141 illustrated in FIG. 13. Otherwise, as illustrated in FIGS. 14 to 18, the connector 140 may be mounted on the lower circuit board 130 as a cut-surface printed circuit board connector (FIG. 14), a three-dimensional pattern connector (FIG. 15), a blade connector (FIG. 16), a rigid printed circuit board connector (FIG. 17), a molded metal connector (FIG. 18), a multi-stage connector (FIG. 19), a silicon connector (FIG. 20), or the like to be vertically fixed to the lower circuit board 130.

A structure in which the pin connector 141 is fixed to the lower surface circuit board 130 will be described as follows.

The pin connector 141 is a standing conductive medium and, as illustrated in FIG. 13, includes a housing 144 which is inserted into the penetration portion 123 provided in the body 121 of the space transformer 120 and is provided with a number of vertical penetration holes 143 penetrating from a top surface to a bottom surface of the housing 144 in parallel with the penetration portion 123, a conductor 145 of which an upper end protrudes from the top surface of the housing 144 and a lower end is bent outwardly from the housing 144 while the conductor 145 is inserted into the penetration hole 143 of the housing 144, a condenser 147 mounted on the top surface of the housing 144, and a ground pin 149 which is a ground transmission line for grounding when the conductor 145 is wire bonded to the unit probe module 110 by a flexible conductive medium. The housing 144 is an insulating member.

The lower end of the conductor 145 of the pin connector 141 having the above-mentioned configuration is mounted on the lower surface circuit board 130, and the upper end of the conductor 145 is wire bonded to be connected to the unit probe module 110 such that an electrical signal is transmitted between the unit probe module 110 and the main circuit board 160.

in addition, the cut-surface printed circuit board connector (FIG. 14), the three-dimensional pattern connector (FIG. 15), the blade connector (FIG. 16), the rigid printed circuit board connector (FIG. 17), the molded metal connector (FIG. 18), the multi-stage connector (FIG. 19), or the silicon connector (FIG. 20), which may replace the pin connector 141, is positioned in the penetration hole 123 provided in the body 121 of the space transformer 120. In addition, the upper end of the conductor 145 positioned inside is wire bonded to the unit probe module 110, and the lower end of the conductor 145 is mounted on the lower circuit board 130 to be vertically positioned.

As illustrated in FIG. 10, while the pin connector 141 is inserted into the penetration portion 123 provided in the body 121 of the space transformer 120, a bolt B that penetrates the lower surface circuit board 130 is fastened to the body 121 such that the body 121 is fastened and fixed to the lower surface circuit board 130. Besides the bolt B, epoxy or adhesive tape may be used to fix the lower surface circuit board 130.

In addition, as illustrated in FIG. 14, the cut-surface printed circuit substrate connector uses a rectangular surface formed by cutting a multi-layered printed circuit board in a rectangular cross-section as a conductive pattern. As illustrated in FIG. 15, the three-dimensional pattern connector is configured by directly and three-dimensionally forming an electric circuit on a surface of a ceramic or plastic resin mold. The entire surface of the mold substrate is configured with conductive patterns.

The blade connector illustrated in FIG. 16 is configured with an insulating frame having a plurality of conductive pins and interval grooves and has a configuration in which conductive pins are inserted at equal or arbitrary intervals between insulating frames having grooves formed at equal intervals.

As illustrated in FIG. 17, the rigid printed circuit board connector has a configuration in which both ends thereof are rigid printed circuit boards and a flexible printed circuit board is connected therebetween. Specifically, one rigid printed circuit board is electrically connected to a circuit board and the other rigid printed circuit board is connected to a probe module.

As illustrated in FIG. 18, the molded metal connector is configured by performing etching on a conductive metal plate and fixing the remaining structure to an insulating frame so as to form conductive patterns on upper and lower surfaces.

FIG. 19 illustrates a space transformer mounted with the multi-stage connector. The multi-stage connector has a configuration in which intermediate parts are joined to separate upper and lower parts from each other and the upper part of the multi-stage connector can be pulled up from the top surface of the body of the space transformer.

The connector illustrated in FIG. 20 is a silicon connector and has a configuration in which a conductive pattern is formed by Cu plating and wet etching after performing etching on a silicon wafer and stacked on a multi-layered printed circuit board.

On the other hand, in the pin connector 141 illustrated in FIG. 13, since the lower surface circuit board 130 is positioned to correspond to the body 121 of the space transformer 120, the conductor 145 of the pin connector 141 that undergoes surface mount does not have a limitation on an internal line design area of a lower circuit board. According to a related art, a number of lower circuit boards are separately arranged to correspond to respective unit probe modules, and for wire bonding between a vertical conductive medium and a pad provided in the lower surface circuit board, a penetration hole of the vertical conductive medium or an area corresponding to this is needed for the lower surface circuit board. Therefore, the internal line design area of the lower circuit board is significantly limited. Recently, with the development of the semiconductor technology, a probe card with fine pitches is required. According to this disclosure, there is an advantage in that the area of the lower surface circuit board 130 is large and the probe card 100 with a fine pitch can be ultimately implemented in terms of large-capacity channel design.

As illustrated in FIGS. 8 and 9, the lower surface circuit board 130 is provided with the mutual connection member 150, the main circuit board 160, and the reinforcement plate 170 as described above. The mutual connection member 150 serves as a medium for electrical connection between the lower surface circuit board 130 and the main circuit board 160. The main circuit board 160 has a function of transmitting an electrical signal transmitted from an external test device to the unit probe module 110 or transmitting a signal generated by a contact between the semiconductor chip and the unit probe module 110 to the test device. Here, the mutual connection member 150 may be a pogo pin or a pressure conductive rubber (PCR).

The reinforcement plate 170 is provided on the rear surface of the main circuit board 160 to physically join the space transformer 120, the mutual connection member 150, and the main circuit board 160 so as to support them. The reinforcement plate 170 may be made of stainless steel, aluminum, invar, kovar, novinite or SKD11, and may have a configuration in which one or more plate(s) are stacked.

Each of the reinforcement plate 170, the main circuit board 160, the mutual connection member 150, and the space transformer 120 is provided with a plurality of opening holes 171 and the opening holes provided in the reinforcement plate 170, the main circuit board 160, the mutual connection member 150, and the space transformer 120 are formed at corresponding positions. Here, the opening hole 171 thoroughly penetrates the reinforcement plate 170, the main circuit board 160, and the mutual connection member 150, but penetrates the space transformer 120 only partially. The opening hole 171 formed in the space transformer 120 and the reinforcement plate 170 may be provided with a thread for fastening a pulling screw 173 or a pushing screw 175.

Each of the opening holes 171 is provided with the pulling screw 173 or the pushing screw 175. The pulling screw 173 and the pulling screw 175 are alternately provided in the opening hole 171, or the pulling screw 173 and the pushing screw 171 may be selectively provided depending on the opening hole 171. As described above, while the pushing screw 173 or the pulling screw 175 are provided in the plurality of the opening holes 171, the pushing screw 173 and the pulling screw 175 are selectively operated to push the space transformer 120 upwardly with respect to the reinforcement plate 170 or pull it downwardly. Accordingly, it is possible to prevent deformation of the space transformer 120 and ultimately maintain flatness of the space transformer 120.

In the above description, the connector and the probe module are wire bonded. However, instead of the wire bonding, they may be electrically connected by means of a flexible circuit board, an anisotropic conductive film, a sub printed circuit board, or a solder ball.

While the exemplary embodiments have been shown and described, it will be understood by those skilled in the art that various changes in form and details may be made thereto without departing from the spirit and scope of this disclosure as defined by the appended claims.

in addition, many modifications can be made to adapt a particular situation or material to the teachings of this disclosure without departing from the essential scope thereof. Therefore, it is intended that this disclosure not be limited to the particular exemplary embodiments disclosed as the best mode contemplated for carrying out this disclosure, but that this disclosure will include all embodiments falling within the scope of the appended claims.

### INDUSTRIAL APPLICABILITY

In the disclosed probe card, the lower surface circuit board mounted to the space transformer has a large area corresponding to an area of the space transformer body, so that there is an advantage in that the main circuit board can be used for general purpose irrespective of the pattern of the probe module in a state where the lower surface circuit board is connected to the main circuit board.

In the disclosed probe card, the standing conductive medium is mounted to the space transformer body in the state where the standing conductive medium is mounted on the lower surface circuit board, so that a problem in which a vertical conductive medium and a lower circuit board are arranged to correspond to each probe module as in the related art can be solved.

In the disclosed probe card, the standing conductive medium is mounted on the lower surface circuit board, and the standing conductive medium is inserted into the penetration portion of the space transformer to be mounted. Therefore, the mounting operation is effective in terms of operation as compared with an operation of inserting the vertical conductive medium into the penetration portion provided in the space transformer body and bonding both ends of wires to the vertical conductive medium and the lower circuit board as in the related art, so that there are advantages in that productivity is excellent and the probe card is structurally stable. In the disclosed probe card, the electrical signal applied to the main circuit board is branched off from the lower surface circuit board via the mutual connection member. Thus, the distance from the branched point to the probe module is shorter than the distance branched off from the existing main circuit board. Therefore, there is an advantage in that signal integrity is excellent.

1. A probe card comprising a space transformer.
wherein the space transformer includes:
a space transformer body having a plurality of probe connection pads arranged on an upper surface;
a lower surface circuit board joined to a lower surface of the space transformer body; and
a standing conductive medium which is mounted on the lower surface circuit board and is inserted into a penetration hole provided in the space transformer body.

2. The probe card according to claim 1, further comprising a flexible conductive medium for electrically connecting the probe connection pad and the standing conductive medium to each other.

3. The probe card according to claim 1,
wherein the lower surface circuit board includes a single or a plurality of circuit boards and has an area corresponding to the area of the space transformer body, and
the standing conductive medium is mounted to protrude from the lower surface circuit board.

4. The probe card according to claim 1, wherein the standing conductive medium is mounted to the lower surface circuit board by a surface mount or an insertion mount.

5. The probe card according to claim 1,
wherein the lower surface circuit board is a printed circuit board,
wherein one end of the printed circuit board is provided with lands to which the standing conductive medium is connected, and the other end of the printed circuit board is provided with a land corresponding to a connection pad of a main circuit board to which an electrical signal is applied from an external test device.

6. The probe card according to claim 1, wherein the standing conductive medium is any one of a pin connector, a cut-surface printed circuit board connector, a three-dimensional pattern connector, a blade connector, a rigid printed circuit board connector, a molded metal connector, a multi-stage pin connector, or a silicon connector.

7. The probe card according to claim 1,
wherein the standing conductive medium has a power/ground transmission line, and
a plurality of condensers are mounted on the power/ground transmission line.

8. The probe card according to claim 6, wherein the pin connector includes a housing provided with penetration holes and conductors inserted into the penetration holes.

9. The probe card according to claim 6, wherein the three-dimensional pattern connector includes a three-dimensional insulating body and a conductive line formed on a surface of the insulating body.

10. The probe card according to claim 6, wherein the cut-surface printed circuit board connector is configured by cutting a multi-layered printed circuit board including a conductive line to expose a part of the conductive line to the cut-surface.

11. The probe card according to claim 6, wherein the blade connector includes a conductive blade, and an insulating frame having a groove into which the conductive blade is inserted.

12. The probe card according to claim 6, wherein a part of the rigid printed circuit board is configured as a flexible circuit board.

13. The probe card according to claim 6, wherein the molded metal connector is configured by performing etching on a conductive metal plate, fixing the remaining metal plate structure to an insulating body, and cutting a connection portion of the metal plate structure, thereby forming a conductive line.

14. The probe card according to claim 6, wherein connectors of the multi-stage pin connector comprises male and female connectors that can be assembled to or disassembled from each other.

15. The probe card according to claim 6, wherein the silicon connector includes a plurality of grooves formed by a silicon etching technique and a conductive line provided in the groove.

16. The probe card according to claim 2, wherein the flexible conductive medium is connected by any one of a wire bonding, a flexible circuit board, an anisotropic conductive film, a sub printed circuit board and a solder ball or a combination thereof.
